(19) United States
(12) Patent Application Publication
(10) Pub. No.: US 2026/0125788 A1
(43) Pub. Date: May 7, 2026

(54) PVD COATING SYSTEM WITH CONTINUOUS MULTI-LAYER CONVEYING MODE AND COATING PROCESS THEREOF

(71) Applicant: GOLD STONE (FUJIAN) ENERGY COMPANY LIMITED, Quanzhou (CN)

(72) Inventors: Yusheng YANG, Quanzhou (CN); Hongqing SHAN, Quanzhou (CN); Liming LAI, Quanzhou (CN); Yijun LIU, Quanzhou (CN)

(73) Assignee: GOLD STONE (FUJIAN) ENERGY COMPANY LIMITED, Quanzhou (CN)

(21) Appl. No.: 19/062,153

(22) Filed: Feb. 25, 2025

(30) Foreign Application Priority Data
Nov. 6, 2024 (CN) 2024115698325

(51) Int. Cl. C23C 14/56; C23C 14/24; C23C 14/32; C23C 14/35; C23C 14/54

(52) U.S. Cl. CPC C23C 14/568; C23C 14/246; C23C 14/32; C23C 14/35; C23C 14/54

(57) ABSTRACT

A PVD coating system with continuous multi-layer conveying mode and a coating process thereof are provided. The system includes a loader, a vacuum feeding chamber, a heating chamber, a coating process chamber module, a vacuum discharge chamber and an unloader connected in sequence through gate valves. The vacuum feeding chamber, the heating chamber, and the vacuum discharge chamber are provided therein with a multi-layer carrier plate conveying mechanism. The coating process chamber module is provided therein with a single-layer carrier plate conveying mechanism or a multi-layer carrier plate conveying mechanism. When the coating process chamber module adopts single-layer conveying, a front end and a rear end of the coating process chamber module are respectively provided with a process feeding buffer chamber and a process discharge buffer chamber. The process feeding buffer chamber and the process discharge buffer chamber are both provided with a multi-layer carrier plate lifting mechanism.

### CROSS REFERENCE TO RELATED APPLICATIONS

This application claims the benefit of priority of Chinese Patent Application No. 2024115698325, filed 6 Nov. 2024. The contents of the above application is all incorporated by reference as if fully set forth herein in its entirety.

### TECHNICAL FIELD

The present disclosure relates to the field of coating devices, and particularly to a PVD coating system with continuous multi-layer conveying mode and a coating process thereof.

### BACKGROUND ART

Currently, mass-produced photovoltaic PVD coating systems on the market generally adopt a continuous coating mode, and carrier plates also enter and exit a vacuum chamber for coating continuously in a single layer and a single piece. Bottlenecks of a production cycle of a photovoltaic PVD continuous coating line at present are carrier-plate transmission time required by the carrier plate entering and exiting the vacuum chamber, time for vacuumizing to a required vacuum degree after the carrier plate entering the vacuum chamber, and time for breaking vacuum in the chamber with a vacuum degree required by a condition for opening a chamber valve, when the carrier plate leaves the chamber and the chamber needs to break the vacuum, etc. If the number of silicon wafers entering and exiting the vacuum chamber in a single time is increased, throughput of a photovoltaic coating device can be improved to a great extent, thus reducing a production cost.

In an existing photovoltaic PVD coating line system, during upgrading and updating of devices, one of the ways to improve the throughput is to continuously increase length and width dimensions of the chamber, and increase designed length and width overall dimensions of the carrier plate for placing the silicon wafer. After the overall dimensions of the chamber are increased, an area of a dust-free room occupied by the device is increased, the large chamber is easier to deform after the chamber is vacuumized, then the device cost is higher, thus the production cost evenly distributed on a single silicon wafer is higher, and a battery cell produced is uncompetitive. After the length and width overall dimensions of the carrier plate are designed to be large, the carrier plate is easy to deform and not rigid enough, and during transmission of the carrier plate, the silicon wafer on the carrier plate is easy to fall off and break; the deformation and insufficient rigidity of the carrier plate cause a region of the carrier plate where the silicon wafer is placed to droop, the silicon wafer in the carrier plate has a non-uniform film thickness during coating, success rates of placing and taking wafer at automatic loader and unloader ends are reduced, and effective operation time of the device is reduced, thus affecting an actual throughput of the device, and indirectly increasing the production cost of the silicon wafer. Therefore, it is a direction of research to improve the throughput of the device without increasing the length and width dimensions of the chamber and the length and width overall dimensions of the carrier plate.

### SUMMARY

The present disclosure aims at providing a PVD coating system with continuous multi-layer conveying mode and a coating process thereof, where multi-layer carrier plates are conveyed simultaneously, thus increasing the number of carrier plates transported by the chamber in a single time, realizing an increase in the number of silicon wafers entering and exiting a vacuum chamber in a single time without increasing the length and width dimensions of the chamber and the length and width overall dimensions of the carrier plates, improving a throughput of a PVD coating device, and reducing a production cost.

In order to achieve the above objective, the present disclosure uses the following technical solutions.

The present disclosure discloses a PVD coating system with continuous multi-layer conveying mode, including: a loader, a vacuum feeding chamber, a heating chamber, a coating process chamber module, a vacuum discharge chamber and an unloader connected in sequence through gate valves, where one or more vacuum feeding chambers and one or more vacuum discharge chambers are provided; the vacuum feeding chamber, the heating chamber, and the vacuum discharge chamber are provided therein with a multi-layer carrier plate conveying mechanism; the coating process chamber module is provided therein with a single-layer carrier plate conveying mechanism or a multi-layer carrier plate conveying mechanism; when the coating process chamber module is provided therein with the single-layer carrier plate conveying mechanism, a front end and a rear end of the coating process chamber module are respectively provided with a process feeding buffer chamber and a process discharge buffer chamber; and the process feeding buffer chamber and the process discharge buffer chamber are both provided with a multi-layer carrier plate lifting mechanism configured to convert between multi-layer carrier plate conveying and single-layer carrier plate conveying.

Further, the multi-layer carrier plate conveying mechanisms provided in the vacuum feeding chamber, the heating chamber, the vacuum discharge chamber are upper and lower two-layer carrier plate conveying mechanisms, the coating process chamber module is provided therein with the single-layer carrier plate conveying mechanism; and the multi-layer carrier plate lifting mechanisms in the process feeding buffer chamber and the process discharge buffer chamber are two-layer carrier plate lifting mechanisms.

Further, the heating chamber is provided therein with upper and lower heaters and a molecular pump configured to vacuumize the heating chamber to a vacuum degree in the coating process chamber module, where the upper and lower heaters are respectively provided at upper and lower sides of the two-layer carrier plate conveying mechanism in the heating chamber.

Further, one vacuum feeding chamber, which is a low vacuum feeding chamber, is provided, and is connected to the heating chamber through the gate valve, so as to form a low and high two-level vacuum, or two vacuum feeding chambers, which are the low vacuum feeding chamber and a medium vacuum feeding chamber connected through the gate valve, are provided, so as to form a low, medium, and high three-level vacuum with the heating chamber;
two vacuum discharge chambers, which are a high vacuum discharge chamber and a low vacuum discharge chamber connected through the gate valve, are provided; or three vacuum discharge chambers, which are a high vacuum discharge chamber, a medium vacuum discharge chamber and a low vacuum discharge chamber connected through the gate valves, are provided; and balance pipelines are provided between the low vacuum feeding chamber and the medium vacuum feeding chamber, and between the medium vacuum discharge chamber and the low vacuum discharge chamber.

Further, the coating process chamber module includes several process chambers communicating with each other, the several process chambers are provided with one or more mixed coating devices of a magnetron sputtering device, an ion plating device and an evaporation coating device.

Further, an isolation chamber is provided between two adjacent coating process chambers of part or all of the coating process chambers.

Further, the process chambers are provided with one or more coating devices.

Further, one or more loaders and one or more unloaders are respectively provided to cooperate.

Further, the unloader and the loader are further provided therebetween with a return conveying mechanism configured to convey a vacant carrier plate back to the loader.

The present disclosure further discloses a PVD coating process with continuous multi-layer conveying mode, using the PVD coating system with continuous multi-layer conveying mode, including steps of:
S1, loading: placing silicon wafers on all carrier plates by the loader, and stacking the carrier plates into multiple layers;
S2, feeding: opening the gate valve leading to the vacuum feeding chamber, conveying the multi-layer carrier plates on the loader simultaneously into the multi-layer carrier plate conveying mechanism in the vacuum feeding chamber, closing the gate valve, and starting to vacuumize the vacuum feeding chamber until reaching a vacuum degree in the heating chamber, where a vacuumizing process is one-level vacuumizing or multi-level vacuumizing;

S3, heating: opening the gate valve leading to the heating chamber, conveying the multi-layer carrier plates in the vacuum feeding chamber simultaneously into the multi-layer carrier plate conveying mechanism in the heating chamber, closing the gate valve, starting to heat the carrier plates, and at the same time, vacuumizing at a higher level to a vacuum degree in the coating process chamber module;

S4, coating: opening the gate valve leading to a coating chamber, conveying the multi-layer carrier plates in the heating chamber into the coating chamber, then closing the gate valve, where the coating chamber adopts single-layer carrier plate conveying or multi-layer carrier plate simultaneous conveying;
when the coating chamber adopts the multi-layer carrier plate simultaneous conveying, the heated multi-layer carrier plates are simultaneously conveyed into the coating chamber for coating;
when the coating chamber adopts the single-layer carrier plate conveying, the heated multi-layer carrier plates are firstly simultaneously conveyed into the process feeding buffer chamber, converted into single layer by the lifting mechanism, and then conveyed continuously in sequence into the coating chamber for coating, and the coated single carrier plate is conveyed into the process discharge buffer chamber and stacked by the lifting mechanism into a state of multiple layers;
S5, discharging: opening the gate valve leading to the vacuum discharge chamber, conveying the coated multi-layer carrier plates in the coating chamber simultaneously to the vacuum discharge chamber, closing the gate valve, performing pressure relief until a vacuum degree being room pressure, and at the same time, cooling the carrier plates, where a pressure relief process is one-level pressure relief or multi-level pressure relief; and
S6, unloading: opening the gate valve leading to the unloader, conveying the multi-layer carrier plates cooled in the vacuum discharge chamber into the unloader, closing the gate valve, and removing the silicon wafers by the unloader.

Further, the carrier plates are conveyed in the vacuum feeding chamber, the heating chamber, the process feeding buffer chamber, the process discharge buffer chamber, and the vacuum discharge chamber in a two-layer simultaneous conveying mode.

Further, the multi-level vacuumizing in the step S2 includes two incremental levels, respectively being a low vacuum feeding stage and a medium vacuum feeding stage, correspondingly executed in the low vacuum feeding chamber and the medium vacuum feeding chamber.

The multi-level pressure relief in the step S5 is three-level decremental pressure relief, respectively being a high vacuum discharge stage, a medium vacuum discharge stage and a low vacuum discharge stage, correspondingly executed in the high vacuum discharge chamber, the medium vacuum discharge chamber and the low vacuum discharge chamber; or two-level decremental pressure relief, respectively being a high vacuum discharge stage and a low vacuum discharge stage, correspondingly executed in the high vacuum discharge chamber and the low vacuum discharge chamber.

Further, the pressure relief in the high vacuum discharge chamber to the medium vacuum discharge chamber or the low vacuum discharge chamber is performed by introducing argon or other rare gases into the high vacuum discharge chamber; the pressure relief in the medium vacuum discharge chamber to the low vacuum discharge chamber is performed by opening the balance pipeline, communicating the medium vacuum discharge chamber with the low vacuum discharge chamber, and balancing vacuum degrees in the two chambers. The pressure relief in the low vacuum discharge chamber to the room pressure is performed by introducing air into the low vacuum discharge chamber or by a CDA vacuum breaking method.

Further, in step S4, the coating is performed by one or more of a mixture of magnetron sputtering coating, ion plating, and evaporation coating; and the coating chamber is formed by connecting a plurality of process chambers together, and each process chamber can be used for coating a front film layer or a back film layer.

Further, one or more loaders and one or more unloaders are respectively used in the loading in step S1 and the unloading in S6 to simultaneously load and unload.

Further, the PVD coating process with continuous multi-layer conveying mode further includes a step S7, returning a vacant carrier plate: returning the vacant carrier plate from which the silicon wafer is removed to the loader.

The present disclosure has the following advantages. In the present disclosure, by providing the multi-layer carrier plate conveying mechanisms in the vacuum feeding chamber and the vacuum discharge chamber, multi-layer carrier plates are conveyed simultaneously, and by converting between multiple layers and single layer by the multi-layer carrier plate lifting mechanism, the number of carrier plates conveyed by the chambers in a single time is increased, thus realizing an increase in the number of silicon wafers entering and exiting the vacuum chambers in a single time without increasing length and width dimensions of the chambers and increasing length and width overall dimensions of the carrier plates, improving throughput of a photovoltaic coating device, reducing a large occupied land area of the device, and lowering investment and production costs.

### BRIEF DESCRIPTION OF DRAWINGS

In order to more clearly illustrate technical solutions of embodiments of the present disclosure, drawings which need to be used in the embodiments will be briefly introduced below. It should be understood that the drawings merely show some embodiments of the present disclosure, and thus should not be considered as limitation to the scope, and those ordinarily skilled in the art still could obtain other relevant drawings according to these drawings, without using any inventive efforts.

FIG. 1 is a structural schematic view of a coating system in Embodiment 1 (magnetron sputtering device).

FIG. 2 is a partial structural view of a feeding part in FIG. 1 (three-stage pressure change);

FIG. 3 is a partial structural view of a coating part in FIG. 1 (single-layer electroplating without isolation chamber).

FIG. 4 is a partial structural view of a discharging part in FIG. 1 (three-stage pressure change).

FIG. 5 is a structural schematic view of the coating system in Embodiment 1 (with an isolation chamber).

FIG. 6 is a structural schematic view of the coating system in Embodiment 1 (ion plating device, evaporation coating device).

FIG. 7 is a structural schematic view of a coating system in Embodiment 2 (two-stage pressure change).

FIG. 8 is a structural schematic view of a coating system in Embodiment 3 (two-layer electroplating).

### Description of Reference Signs of Main Elements

1, loader;
2, vacuum feeding chamber; 21, low vacuum feeding chamber; 22, medium vacuum feeding chamber;
3, heating chamber; 31, upper and lower heater;
4, process feeding buffer chamber;
5, coating process chamber module; 51, process chamber; 52, isolation chamber; 53, magnetron sputtering device; 54, ion plating device; 55, evaporation coating device; 56, coating device;
6, process discharge buffer chamber;
7, vacuum discharge chamber; 71, high vacuum discharge chamber; 72, medium vacuum discharge chamber; 73, low vacuum discharge chamber;
8, unloader;
9, return conveying mechanism;
10, carrier-plate lifting mechanism;
20, carrier-plate conveying mechanism;
30, balance pipeline.

### DETAILED DESCRIPTION OF EMBODIMENTS

In order to make objectives, technical solutions and advantages of embodiments of the present disclosure clearer, technical solutions in the embodiments of the present disclosure will be described clearly and completely below in conjunction with the drawings in the description. Apparently, only some but not all embodiments of the present disclosure are described. Based on the embodiments in the present disclosure, all of other embodiments obtained by those ordinarily skilled in the art without using any inventive efforts shall fall within the scope of protection of the present disclosure.

In the present disclosure, unless otherwise specified, directional terms such as “upper, lower, left, and right” are generally understood in conjunction with orientation shown in the drawings and practical application.

Besides, the terms “first” and “second” are merely used for descriptive purpose, but should not be construed as indicating or implying importance in the relativity or implicitly indicating the number of a related technical feature. Thus, defining a feature with “first” or “second” may explicitly or implicitly mean that one or more such features are included. In the description of the present disclosure, “a plurality of” means two or more, unless otherwise explicitly defined.

In the present disclosure, unless otherwise explicitly specified and defined, a first feature being “on” or “under” a second feature may mean that the first feature is in direct contact with the second feature, or the first feature is in indirect contact with the second feature via an intermediary. Moreover, the first feature being “over”, “above” and “on top of” the second feature may be the case that the first feature is directly above or not directly above the second feature, or only means that the first feature is at a horizontal height higher than the second feature. The first feature being “under”, “beneath” or “below” a second feature may include a case where the first feature is directly below or not directly below the second feature, or only means that the first feature is at a horizontal height lower than the second feature.

Endpoints and any value of ranges disclosed herein are not limited to the precise ranges or values, and these ranges or values should be understood as encompassing values close to these ranges or values. For numerical ranges, endpoint values of various ranges can be combined with each other, endpoint values of various ranges and individual point values can be combined with each other, and individual point values can be combined with each other to obtain one or more new numerical ranges, and such numerical ranges should be construed as being specifically disclosed herein. The terms “optional” and “optionally” both mean possibly including or not (or possibly being present or possibly being not present).

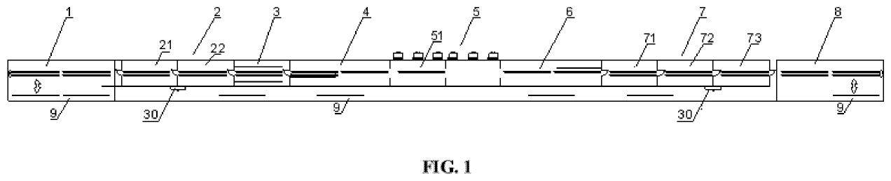

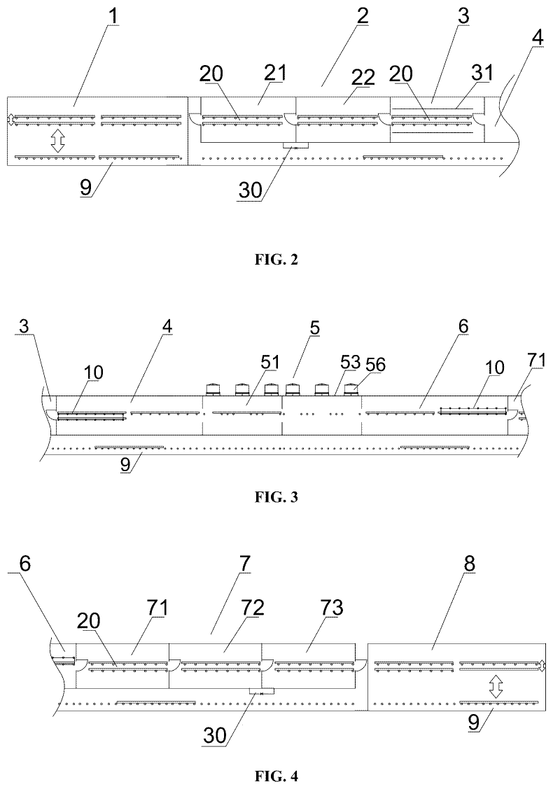

As shown in FIG. 1 to FIG. 8, the present disclosure discloses a PVD coating system with continuous multi-layer conveying mode, which includes a loader 1, a vacuum feeding chamber 2, a heating chamber 3, a coating process chamber module 5, a vacuum discharge chamber 7 and an unloader 8 connected in sequence through gate valves.

One or more vacuum feeding chambers 2 and one or more vacuum discharge chambers 7 are provided.

The one or more vacuum feeding chambers 2, the heating chamber 3, and the one or more vacuum discharge chambers 7 are provided therein with a multi-layer carrier plate conveying mechanism 20.

The coating process chamber module 5 is provided therein with a single-layer carrier plate conveying mechanism 20 or a multi-layer carrier plate conveying mechanism 20.

When the coating process chamber module 5 is provided therein with the single-layer carrier plate conveying mechanism 20, a front end and a rear end of the coating process chamber module 5 are respectively provided with a process feeding buffer chamber 4 and a process discharge buffer chamber 6. The process feeding buffer chamber 4 and the process discharge buffer chamber 6 are both provided with a multi-layer carrier plate lifting mechanism 10 configured to convert between multi-layer carrier plate conveying and single-layer carrier plate conveying.

In the present disclosure, by providing the multi-layer carrier plate conveying mechanism 20 in the vacuum feeding chamber 2, the heating chamber 3 and the vacuum discharge chamber 7, multi-layer carrier plates are conveyed simultaneously, and by converting between multiple layers and single layer by the multi-layer carrier plate lifting mechanism 10, the number of carrier plates conveyed by the chambers in a single time is increased, thus realizing an increase in the number of silicon wafers entering and exiting the vacuum chambers in a single time without increasing length and width dimensions of the chambers and increasing length and width overall dimensions of the carrier plates, improving throughput of a photovoltaic coating device, and reducing a production cost.

### Embodiment 1

As shown in FIG. 1 to FIG. 4, two vacuum feeding chambers 2 are provided in the present embodiment, namely, a low vacuum feeding chamber 21 and a medium vacuum feeding chamber 22 connected through gate valves, and a heating chamber 3 is connected through the gate valve, so as to form three levels, i.e., low, medium and high levels, of vacuum. Three vacuum discharge chambers 7 are provided, namely, a high vacuum discharge chamber 71, a medium vacuum discharge chamber 72 and a low vacuum discharge chamber 73 connected through the gate valves. By increasing the number of vacuum chambers, total time for vacuumizing and breaking vacuum by pressure relief can be greatly reduced, which is applicable to high-throughput and high-speed coating cycle.

In order to further reduce the time for vacuumizing and breaking vacuum, balance pipelines 30 are provided between the low vacuum feeding chamber 21 and the medium vacuum feeding chamber 22, and between the medium vacuum discharge chamber 72 and the low vacuum discharge chamber 73. By opening the balance pipelines 30, vacuum degrees between the low vacuum feeding chamber 21 and the medium vacuum feeding chamber 22, and between the medium vacuum discharge chamber 72 and the low vacuum discharge chamber 73 are kept consistent.

In the present embodiment, the multi-layer carrier plate conveying mechanisms in the low vacuum feeding chamber 21, the medium vacuum feeding chamber 22, the heating chamber 3, the high vacuum discharge chamber 71, the medium vacuum discharge chamber 72, and the low vacuum discharge chamber 73 are upper and lower two-layer carrier plate conveying mechanisms 20, and the conveying mechanism provided in the coating process chamber module 5 is the single-layer carrier plate conveying mechanism 20. The multi-layer carrier plate lifting mechanisms in the process feeding buffer chamber 4 and the process discharge buffer chamber 6 are two-layer carrier plate lifting mechanisms 10.

The unloader 8 and the loader 1 in the present embodiment are further provided therebetween with a return conveying mechanism 9 configured to convey a vacant carrier plate back to the loader 1.

Specifically:
the present embodiment discloses a PVD coating system with continuous multi-layer conveying mode, which includes the loader 1, the low vacuum feeding chamber 21, the medium vacuum feeding chamber 22, the heating chamber 3, the coating process chamber module 5, the high vacuum discharge chamber 71, the medium vacuum discharge chamber 72, the low vacuum discharge chamber 73, the unloader 8 and the return conveying mechanism 9 connected in sequence through the gate valves. In the above, two ends (front and back) of the coating process chamber module 5 are provided with the process feeding buffer chamber 4 and the process discharge buffer chamber 6.

The upper and lower two-layer carrier plate conveying mechanism 20 is a conveyor provided with two-layer conveying lines, with consistent upper and lower conveying speeds. The two-layer carrier plate lifting mechanism 10 can independently control single operation of the two-layer conveying lines, and cooperate with a lifting assembly to realize up and down movement, so as to realize conversion between multi-layer carrier plate conveying and single-layer carrier plate conveying. The two-layer carrier plate lifting mechanism 10 in the present disclosure can firstly convey an upper carrier plate first to a single-layer carrier plate buffering position, and can also firstly convey a lower carrier plate to the single-layer carrier plate buffering position. The carrier-plate lifting mechanism 10 can also omit the single-layer carrier plate buffering position beside, and is directly butt-jointed to the coating process chamber module. Therefore, the carrier-plate lifting mechanism 10 in the present disclosure is not limited to this specific structure.

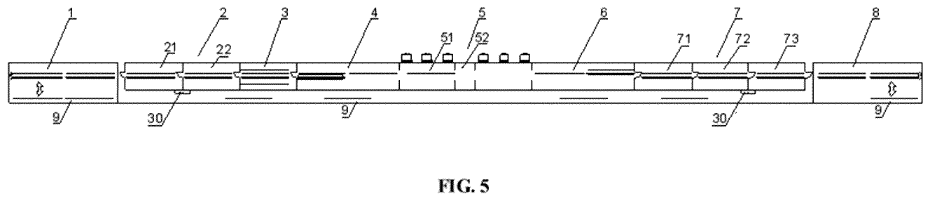

The coating process chamber module 5 includes several process chambers 51 communicating with each other, and different numbers of process chambers 51 are provided according to coating requirements. Each process chamber 51 may be chosen to coat a front film layer of a silicon wafer or a back film layer of the silicon wafer according to coating requirements. As shown in FIG. 5, according to practical process requirements, an isolation chamber 52 can be added between adjacent process chambers 51, acting as a chamber for isolating and preventing doping of film layers of different materials when coating film layers of different materials.

The heating chamber 3 is provided therein with upper and lower heaters 31 and a molecular pump configured to pump a vacuum degree to be consistent with or close to a vacuum degree in the process chamber 51, where the upper and lower heaters 31 are respectively provided at upper and lower sides of the two-layer carrier plate conveying mechanism 20 in the heating chamber 3, and can heat upper and lower two-layer carrier plates simultaneously.

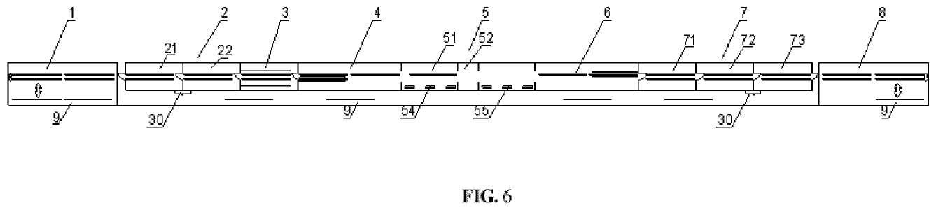

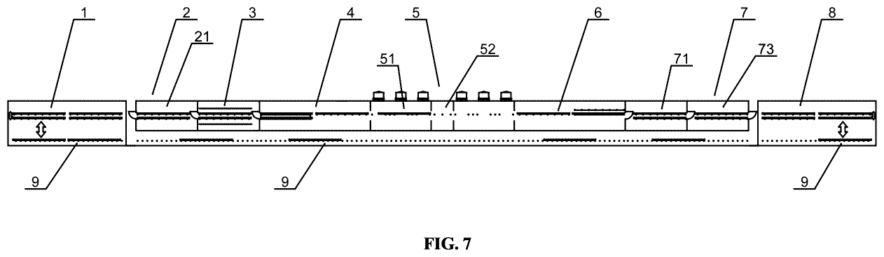

As shown in FIG. 6, one process chamber 51 can be provided with a magnetron sputtering device 53, an ion plating device 54 or an evaporation coating device 55. The whole coating process chamber module 5 can select a proper coating mode according to requirements of film layers, and can select one coating mode or mixed coating modes.

One process chamber 51 is provided with one or more coating devices 56 so as to meet requirements of the coating process.

According to conveying speeds of two layers, one or more loaders 1 and one or more unloaders 8 are respectively provided to cooperate and simultaneously load and unload.

A coating process using the coating system of Embodiment 1 includes the following steps:
S1, loading: placing silicon wafers on all the carrier plates by the loader 1, and placing the carrier plates on the upper and lower two-layer carrier plate conveying mechanism 20, where in order to match a coating speed, two loaders 1 are used for simultaneous loading;
S2, feeding: opening the gate valve leading to the low vacuum feeding chamber 21, conveying upper and lower two-layer carrier plates with the silicon wafers on the loader 1 simultaneously onto the upper and lower two-layer carrier plate conveying mechanism 20 in the low vacuum feeding chamber 21, closing the gate valve, starting to vacuumize, and when reaching a set vacuum degree, opening the balance pipeline 30 connecting the low vacuum feeding chamber 21 and the medium vacuum feeding chamber 22, until the vacuum degree being consistent with or close to that in the medium vacuum feeding chamber 22;
then opening the gate valve leading to the medium vacuum feeding chamber 22, conveying the upper and lower two-layer carrier plates in the low vacuum feeding chamber 21 simultaneously to the two-layer carrier plate conveying mechanism 20 in the medium vacuum feeding chamber 22, closing the gate valve and the balance pipeline 30, and starting to vacuumize until the vacuum degree being consistent with or close to that in the heating chamber 3;
S3, heating: opening the gate valve leading to the heating chamber 3, conveying the upper and lower two-layer carrier plates in the medium vacuum feeding chamber 22 simultaneously onto the upper and lower two-layer carrier plate conveying mechanism 20 in the heating chamber 3, closing the gate valve, starting to heat the upper and lower two-layer carrier plates by the upper and lower heaters 31, and at the same time, vacuumizing the chamber at a higher level until the vacuum degree being consistent with or close to the vacuum degree in the coating chamber, where water vapor in the heating chamber 3, part of water vapor on the carrier plates and part of water vapor on the silicon wafers are pumped away by the molecular pump in the heating chamber 3, and the heaters heat so that the molecular pump more easily pumps away the water vapor;
S4, coating: opening the gate valve leading to the coating chamber, firstly conveying the upper and lower two-carrier plates having been heated simultaneously onto the two-layer carrier plate lifting mechanism 10 in the process feeding buffer chamber 4, closing the gate valve, converting the two carrier plates by the lifting mechanism into single layer to be conveyed continuously onto the single-layer carrier plate conveying mechanism 20 in the coating chamber for continuous coating, conveying the single carrier plate after the coating into the process discharge buffer chamber 6, and staking the carrier plates into a state of upper and lower layers by the lifting mechanism, where the silicon wafers are continuous when being coated in the coating chamber, that is, the coating process is performed while the carrier plates are conveyed at a specific speed, and the carrier plates in the coating chamber can be continuously coated one next to another, and the carrier plates can have no gap or a certain gap;
according to requirements of film layers, the coating is performed by one or a mixture of more of magnetron sputtering coating, ion plating and evaporation coating; and the coating chamber is formed by connecting a plurality of process chambers 51 together, and each process chamber 51 can be used for coating a front film layer or a back film layer;
S5, discharging: opening the gate valve leading to the high vacuum discharge chamber 71, conveying the upper and lower two-layer carrier plates after the coating in the process discharge buffer chamber 6 simultaneously to the two-layer carrier plate conveying mechanism 20 in the high vacuum discharge chamber 71, closing the gate valve, introducing a fixed amount of argon or other inert gases for pressure relief, and at the same time, cooling the carrier plates, until the vacuum degree being consistent with or close to that in the medium vacuum discharge chamber 72;
then opening the gate valve leading to the medium vacuum discharge chamber 72, conveying the upper and lower two-layer carrier plates in the high vacuum discharge chamber 71 simultaneously to the two-layer carrier plate conveying mechanism 20 in the medium vacuum discharge chamber 72, then closing the gate valve, and vacuumizing the high vacuum discharge chamber 71 to be isobaric with the coating process chamber module 5;
at the same time, introducing a fixed amount of argon or other inert gases into the medium vacuum discharge chamber 72 for pressure relief to a set value, and at the same time, cooling the carrier plates, opening the balance pipeline 30 connecting the medium vacuum discharge chamber 72 and the low vacuum discharge chamber 73, and vacuum degrees in the medium vacuum discharge chamber 72 and the low vacuum discharge chamber 73 being the same or close after balance;
then opening the gate valve leading to the low vacuum discharge chamber 73, conveying the upper and lower two-layer carrier plates in the medium vacuum discharge chamber 72 simultaneously to the two-layer carrier plate conveying mechanism 20 in the low vacuum discharge chamber 73, then closing the gate valve, and vacuumizing the medium vacuum discharge chamber 72 to a set vacuum value; and
introducing air into the low vacuum discharge chamber 73 or breaking vacuum by a CDA vacuum breaking method, and at the same time, cooling the carrier plates until the vacuum degree being consistent with or close to that of room pressure;
S6, unloading: opening the gate valve leading to the unloader 8, conveying the upper and lower two-layer carrier plates cooled in the medium vacuum discharge chamber 72 simultaneously into the unloader 8, closing the gate valve, removing the silicon wafers by the unloader 8, and at the same time, vacuumizing the low vacuum discharge chamber 73 to a set vacuum value, where in order to match a coating speed, two unloaders 8 cooperate for simultaneous unloading; and
S7, returning a vacant carrier plate: returning the vacant carrier plate from which the silicon wafer is removed to the loader 1.

### Embodiment 2

As shown in FIG. 7, the present embodiment is applicable to: when the required throughput may be slightly reduced, for example, when a PVD coating system with medium throughput is designed, the low vacuum feeding chamber 21 can be vacuumized to a higher vacuum degree consistent with or close to that in the heating chamber 3, and the medium vacuum feeding chamber 22 is omitted. The carrier plates in the low vacuum feeding chamber 21 are conveyed into the heating chamber 3. The carrier plates leave the vacuum in the same way, that is, the medium vacuum discharge chamber 72 is omitted, and the carrier plates in the high vacuum discharge chamber 71 are conveyed into the low vacuum discharge chamber 73.

The present Embodiment 2 is different from Embodiment 1 in that the medium vacuum feeding chamber 22 and the medium vacuum discharge chamber 72 are omitted. That is, one vacuum feeding chamber 2, namely, the low vacuum feeding chamber 21, is provided in the present embodiment, and is connected to the heating chamber 3 through the gate valve, so as to form two levels, i.e., low and high levels, of vacuum. Two vacuum discharge chambers 7 are provided, namely, the high vacuum discharge chamber 71 and the low vacuum discharge chamber 73 connected through the gate valve, so as to form two levels, i.e., high and low levels, of pressure relief to break vacuum.

Other technical features are consistent with those in Embodiment 1.

After the medium vacuum feeding chamber 22 and the medium vacuum discharge chamber 72 are omitted, not only the manufacturing cost of the chambers can be reduced, but also the occupied land cost of production workshop can be reduced.

Specifically:
the present embodiment discloses a PVD coating system with continuous multi-layer conveying mode, which includes the loader 1, the low vacuum feeding chamber 21, the heating chamber 3, the coating process chamber module 5, the high vacuum discharge chamber 71, the low vacuum discharge chamber 73, the unloader 8 and the return conveying mechanism 9 connected in sequence through the gate valves. In the above, two front and back ends of the coating process chamber module 5 are provided with the process feeding buffer chamber 4 and the process discharge buffer chamber 6.

The multi-layer carrier plate conveying mechanisms provided in the low vacuum feeding chamber 21, the heating chamber 3, the high vacuum discharge chamber 71, and the low vacuum discharge chamber 73 in the present embodiment are upper and lower two-layer carrier plate conveying mechanisms 20, the conveying mechanism provided in the coating process chamber module 5 is a single-layer carrier plate conveying mechanism, and the multi-layer carrier plate lifting mechanisms in the process feeding buffer chamber 4 and the process discharge buffer chamber 6 are two-layer carrier plate lifting mechanisms 10.

A coating process using the coating system of Embodiment 2 is different from the coating process using the coating system of Embodiment 1 in step S2 feeding and step S5 discharging. Other steps are consistent with those in Embodiment 1.

Specifically:
S2, feeding: opening the gate valve leading to the low vacuum feeding chamber 21, conveying the upper and lower two-layer carrier plates with the silicon wafers simultaneously onto the upper and lower two-layer carrier plate conveying mechanism 20 in the low vacuum feeding chamber 21, closing the gate valve, starting to vacuumize the low vacuum feeding chamber 21 until the vacuum degree being consistent with or close to that in the heating chamber 3;
S5, discharging: opening the gate valve leading to the high vacuum discharge chamber 71, conveying the upper and lower two-layer carrier plates after the coating in the process discharge buffer chamber 6 simultaneously to the two-layer carrier plate conveying mechanism 20 in the high vacuum discharge chamber 71, closing the gate valve, introducing a fixed amount of argon or other inert gases for pressure relief, and at the same time cooling the carrier plates, until the vacuum degree being consistent with or close to that in the low vacuum discharge chamber 73;
then opening the gate valve leading to the low vacuum discharge chamber 73, conveying the upper and lower two-layer carrier plates in the high vacuum discharge chamber 71 simultaneously to the two-layer carrier plate conveying mechanism 20 in the low vacuum discharge chamber 73, then closing the gate valve, and vacuumizing the high vacuum discharge chamber 71 to be isobaric with or close to that in the coating process chamber module 5; and
at the same time, introducing air into the low vacuum discharge chamber 73 or breaking vacuum by a CDA vacuum breaking method, and at the same time, cooling the carrier plates until the vacuum degree being consistent with or close to that of room pressure.

### Embodiment 3

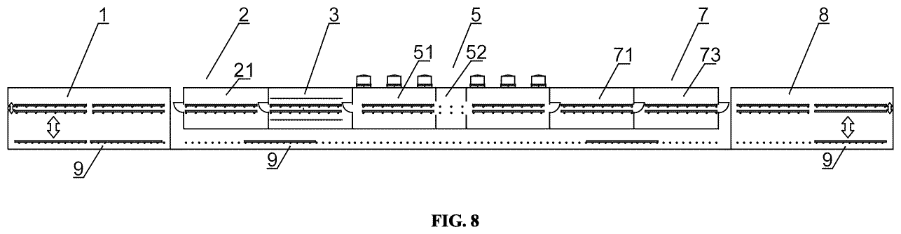

As shown in FIG. 8, the present embodiment is different from Embodiment 2 in that the conveying mechanism provided in the coating process chamber module 5 in the present embodiment is a two-layer carrier plate conveying mechanism 20, and two front and rear ends of the coating process chamber module 5 do not need to be provided with the process feeding buffer chamber 4 or the process discharge buffer chamber 6.

Other structures are consistent with those in Embodiment 2.

Specifically:
Embodiment 3 discloses a PVD coating system with continuous multi-layer conveying mode, which includes the loader 1, the low vacuum feeding chamber 21, the medium vacuum feeding chamber 22, the heating chamber 3, the coating process chamber module 5, the high vacuum discharge chamber 71, the medium vacuum discharge chamber 72, the low vacuum discharge chamber 73, the unloader 8 and the return conveying mechanism 9 connected in sequence through the gate valves.

The multi-layer carrier plate conveying mechanisms in the low vacuum feeding chamber 21, the medium vacuum feeding chamber 22, the heating chamber 3, the high vacuum discharge chamber 71, the medium vacuum discharge chamber 72, and the low vacuum discharge chamber 73 in the present embodiment are upper and lower two-layer carrier plate conveying mechanisms 20, and the conveying mechanism provided in the coating process chamber module 5 is a two-layer carrier plate conveying mechanism 20.

A coating process using the coating system of Embodiment 3 is different from the coating process using the coating system of Embodiment 2 in step S4 coating process. Other steps are consistent with those in Embodiment 2.

Specifically:
S4, coating: opening the gate valve leading to the coating chamber, conveying the upper and lower two-layer carrier plates having been heated simultaneously onto the two-layer carrier plate conveying mechanism 20 in the coating chamber, closing the gate valve, and then conveying the carrier plates for continuous coating.

Preferred embodiments of the present disclosure are described in detail in the above, but the present disclosure is not limited thereto. Within the scope of technical concept of the present disclosure, a number of simple modifications can be made to the technical solutions of the present disclosure, including combining various technical features in any other suitable ways, and these simple modifications and combinations should also be regarded as the contents disclosed in the present disclosure, and all fall within the scope of the present disclosure.

What is claimed is:

1. A PVD coating system with continuous multi-layer conveying mode, comprising: a loader, a vacuum feeding chamber, a heating chamber, a coating process chamber module, a vacuum discharge chamber and an unloader connected in sequence through gate valves, wherein one or more vacuum feeding chambers and one or more vacuum discharge chambers are provided; the vacuum feeding chamber, the heating chamber, and the vacuum discharge chamber are provided therein with a multi-layer carrier plate conveying mechanism; the coating process chamber module is provided therein with a single-layer carrier plate conveying mechanism or a multi-layer carrier plate conveying mechanism; when the coating process chamber module is provided therein with the single-layer carrier plate conveying mechanism, a front end and a rear end of the coating process chamber module are respectively provided with a process feeding buffer chamber and a process discharge buffer chamber; and the process feeding buffer chamber and the process discharge buffer chamber are both provided with a multi-layer carrier plate lifting mechanism configured to convert between multi-layer carrier plate conveying and single-layer carrier plate conveying.

2. The PVD coating system with continuous multi-layer conveying mode according to claim 1, wherein the multi-layer carrier plate conveying mechanisms provided in the vacuum feeding chamber, the heating chamber, the vacuum discharge chamber are upper and lower two layer-carrier plate conveying mechanisms, the coating process chamber module is provided therein with the single-layer carrier plate conveying mechanism; and the multi-layer carrier plate lifting mechanisms in the process feeding buffer chamber and the process discharge buffer chamber are two-layer carrier plate lifting mechanisms.

3. The PVD coating system with continuous multi-layer conveying mode according to claim 2, wherein the heating chamber is provided therein with upper and lower heaters and a molecular pump configured to vacuumize the heating chamber to a vacuum degree in the coating process chamber module, wherein the upper and lower heaters are respectively provided at upper and lower sides of the two-layer carrier plate conveying mechanism in the heating chamber.

4. The PVD coating system with continuous multi-layer conveying mode according to claim 3, wherein one vacuum feeding chamber, which is a low vacuum feeding chamber, is provided, and is connected to the heating chamber through the gate valve, so as to form a low and high two-level vacuum, or two vacuum feeding chambers, which are the low vacuum feeding chamber and a medium vacuum feeding chamber connected through the gate valve, are provided, so as to form low, medium, and high three-level vacuum with the heating chamber;
two vacuum discharge chambers, which are a high vacuum discharge chamber and a low vacuum discharge chamber connected through the gate valve, are provided; or three vacuum discharge chambers, which are a high vacuum discharge chamber, a medium vacuum discharge chamber and a low vacuum discharge chamber connected through the gate valves, are provided; and balance pipelines are provided between the low vacuum feeding chamber and the medium vacuum feeding chamber, and between the medium vacuum discharge chamber and the low vacuum discharge chamber.

5. The PVD coating system with continuous multi-layer conveying mode according to claim 1, wherein the coating process chamber module comprises several process chambers communicating with each other, the several process chambers are provided with one or more mixed coating devices of a magnetron sputtering device, an ion plating device and an evaporation coating device.

6. The PVD coating system with continuous multi-layer conveying mode according to claim 5, wherein an isolation chamber is provided between two adjacent coating process chambers of part or all of the coating process chambers.

7. The PVD coating system with continuous multi-layer conveying mode according to claim 5, wherein the process chambers are provided with one or more coating devices.

8. The PVD coating system with continuous multi-layer conveying mode according to claim 1, wherein one or more loaders and one or more unloaders are respectively provided to cooperate.

9. The PVD coating system with continuous multi-layer conveying mode according to claim 1, wherein the unloader and the loader are further provided therebetween with a return conveying mechanism configured to convey a vacant carrier plate back to the loader.

10. A PVD coating process with continuous multi-layer conveying mode, using the PVD coating system with continuous multi-layer conveying mode according to claim 1, comprising steps of:
S1, loading: placing silicon wafers on all carrier plates by the loader, and stacking the carrier plates into multiple layers;
S2, feeding: opening the gate valve leading to the vacuum feeding chamber, conveying multi-layer carrier plates on the loader simultaneously into the multi-layer carrier plate conveying mechanism in the vacuum feeding chamber, closing the gate valve, and starting to vacuumize the vacuum feeding chamber until reaching a vacuum degree in the heating chamber, wherein a vacuumizing process is one-level vacuumizing or multi-level vacuumizing;
S3, heating: opening the gate valve leading to the heating chamber, conveying the multi-layer carrier plates in the vacuum feeding chamber simultaneously into the multi-layer carrier plate conveying mechanism in the heating chamber, closing the gate valve, starting to heat the carrier plates, and at the same time, vacuumizing at a higher level to a vacuum degree in the coating process chamber module;
S4, coating: opening the gate valve leading to a coating chamber, conveying the multi-layer carrier plates in the heating chamber into the coating chamber, then closing the gate valve, wherein the coating chamber adopts single-layer carrier plate conveying or multi-layer carrier plate simultaneous conveying;
when the coating chamber adopts the multi-layer carrier plate simultaneous conveying, the heated multi-layer carrier plates are simultaneously conveyed into the coating chamber for coating;
when the coating chamber adopts the single-layer carrier plate conveying, the heated multi-layer carrier plates are firstly simultaneously conveyed into the process feeding buffer chamber, converted into single-layer by the lifting mechanism, and then conveyed continuously in sequence into the coating chamber for coating, and the coated single-layer carrier plate is conveyed into the process discharge buffer chamber and stacked by the lifting mechanism into a state of multi-layer;
S5, discharging: opening the gate valve leading to the vacuum discharge chamber, conveying the coated multi-layer carrier plates in the coating chamber simultaneously to the vacuum discharge chamber, closing the gate valve, performing pressure relief until a vacuum degree being room pressure, and at the same time, cooling the carrier plates, wherein a pressure relief process is one-level pressure relief or multi-level pressure relief; and
S6, unloading: opening the gate valve leading to the unloader, conveying the multi-layer carrier plates cooled in the vacuum discharge chamber into the unloader, closing the gate valve, and removing the silicon wafers by the unloader.

11. The PVD coating process with continuous multi-layer conveying mode according to claim 10, wherein the carrier plates are conveyed in the vacuum feeding chamber, the heating chamber, the process feeding buffer chamber, the process discharge buffer chamber, and the vacuum discharge chamber in a two-layer simultaneous conveying mode.

12. The PVD coating process with continuous multi-layer conveying mode according to claim 11, wherein the multi-level vacuumizing in the step S2 comprises two incremental levels, respectively being a low vacuum feeding stage and a medium vacuum feeding stage, correspondingly executed in the low vacuum feeding chamber and the medium vacuum feeding chamber; and
the multi-level pressure relief in the step S5 is three-level decremental pressure relief, respectively being a high vacuum discharge stage, a medium vacuum discharge stage and a low vacuum discharge stage, correspondingly executed in the high vacuum discharge chamber, the medium vacuum discharge chamber and the low vacuum discharge chamber; or two-level decremental pressure relief, respectively being a high vacuum discharge stage and a low vacuum discharge stage, correspondingly executed in the high vacuum discharge chamber and the low vacuum discharge chamber.

13. The PVD coating process with continuous multi-layer conveying mode according to claim 12, wherein the pressure relief in the high vacuum discharge stage to the medium vacuum discharge stage or the low vacuum discharge stage is performed by introducing argon or other rare gases into the high vacuum discharge chamber; the pressure relief in the medium vacuum discharge stage to the low vacuum discharge stage is performed by opening the balance pipeline, communicating the medium vacuum discharge chamber with the low vacuum discharge chamber, and balancing vacuum degrees in the two chambers; and the pressure relief in the low vacuum discharge stage to the room pressure is performed by introducing air into the low vacuum discharge chamber or by a CDA vacuum breaking method.

14. The PVD coating process with continuous multi-layer conveying mode according to claim 10, wherein in step S4, the coating is performed by one or more of a mixture of magnetron sputtering coating, ion plating, and evaporation coating; and the coating chamber is formed by connecting a plurality of process chambers together, and each process chamber can be used for coating a front film layer or a back film layer.

15. The PVD coating process with continuous multi-layer conveying mode according to claim 10, wherein one or more loaders and one or more unloaders are respectively used in the loading in step S1 and the unloading in S6 to simultaneously load and unload.

16. The PVD coating process with continuous multi-layer conveying mode according to claim 10, further comprising a step S7, returning a vacant carrier plate: returning the vacant carrier plate from which the silicon wafer is removed to the loader.
